(19) United States
(12) Patent Application Publication
(10) Pub. No.: US 2005/0092245 A1
(43) Pub. Date: May 5, 2005

(54) Plasma chemical vapor deposition apparatus having an improved nozzle configuration

(76) Inventors: Ahn-Sik Moon, Suwon-si (KR); Yun-Sik Yang, Suwon-si (KR); Jae-Hyun Han, Gyeonggi-do (KR); Joo-Pyo Hong, Seoul (KR); Seung-Ki Chae, Seoul (KR); In-Cheol Lee, Gyeonggi-do (KR); Jong-Koo Lee, Anyang-si (KR); Dae-Hyun Kim, Gyeonggi-do (KR)

Correspondence Address: HARNESS, DICKEY & PIERCE, P.L.C., P.O. BOX 8910, RESTON, VA, 20195, US

(21) Appl. No.: 10/918,490

(22) Filed: Aug. 16, 2004

(30) Foreign Application Priority Data
Nov. 3, 2003 (KR) 2003-77396
Apr. 12, 2004 (KR) 2004-25097

(51) Int. Cl. C23C 16/00

(52) U.S. Cl. 118/715

(57) ABSTRACT

Provided is a high density plasma chemical vapor deposition (HDP-CVD) apparatus that includes a plurality of nozzles and/or injection pipes arranged for injecting a source gas mixture into a reaction chamber. The nozzles will each include an outlet region that includes a plurality of outlet channels or ports, the outlet channels are, in turn, configured to have a sufficiently small width and a sufficient length to suppress the formation of a plasma within the source gases passing through the respective nozzles. By suppressing the formation of a plasma within the nozzles, the thickness of deposits formed on the nozzles during the deposition processes can be maintained at a level generally no greater than deposits formed on the other chamber surfaces. This control of the deposit thickness allows the nozzles to be cleaned effectively by the same cleaning process applied to the chamber.

### CROSS-REFERENCE TO RELATED APPLICATIONS

This application claims priority from Korean Patent Application No. 2003-77396, which was filed on Nov. 3, 2003, and Korean Patent Application No. 2004-25097, which was filed on Apr. 12, 2004, in the Korean Intellectual Property Office, the disclosures of which are incorporated herein in their entirety by reference.

### BACKGROUND OF THE INVENTION

1. Field of the Invention

The present invention relates to an apparatus used for manufacturing semiconductor devices and, more particularly, to a plasma chemical vapor deposition (“CVD”) apparatus for depositing a layer of a material on a semiconductor substrate using plasma and a nozzle configuration useful in such a plasma CVD apparatus.

2. Description of Related Art

A significant deposition process utilized repeatedly during the manufacture of semiconductor devices is a chemical vapor deposition (CVD) process, which may be used to form or deposit a wide variety of films on semiconductor substrates through the chemical reaction of one or more source gases. More recently, variations on the conventional CVD processes including high density plasma chemical vapor deposition (HDP-CVD) processes have been developed and widely adopted.

Compared with conventional CVD, HDP-CVD processes are generally better able to fill spaces or gaps having higher aspect ratios. In the HDP-CVD apparatus, high density plasma ions are produced in a process chamber for a specific combination of source gases to deposit a layer of a material having a controlled composition on a wafer. During this deposition, however, an etching process may be conducted using an inert gas to improve the gap filling performance and reduce the occurrence of voids within the deposited layer.

A HDP-CVD apparatus includes a plurality of nozzles installed in a chamber. A variety of source gases may be injected into the chamber through the various the nozzles in controlled quantities to produce a range of gas mixtures within the chamber. A high-frequency power, such as radio frequency (RF) or microwave (MW) power, may then be applied to a coil arranged around the outside of the chamber to excite the gas or gas mixture within the chamber and form or “strike” a plasma and promote the intended chemical reaction(s).

Throughout the deposition process, however, certain reactive products and byproducts may be created and deposited on the inner surfaces of the chamber. Because an accumulation of these deposits can separate from the inner surfaces and result in particulate contamination on subsequent substrates, conventional CVD deposition processes generally incorporate a regular periodic cleaning step to remove the depositions from the inner surfaces of the chamber. The cleaning step will typically use an etching gas and be performed after processing a specified number of wafers through the deposition process.

As shown in FIG. 24, the nozzles conventionally used in the HDP-CVD include a single, relatively large and centrally located through-hole that forms an injection path for the source gas(es) entering the chamber. However, as a result of the apparatus configuration, before the source gases are injected into the chamber, they can be excited into a plasma state within the through-hole of the nozzle by the high-frequency power being applied to the chamber.

Depending on the gas mixture present in the nozzle, the source gases may react with one another to deposit a film on the inner wall of the nozzle. Typically starting from the terminal or outlet end of the nozzle, the quantity of the material deposited within the nozzle tends to increase and extend further into the through-hole over time. The deposits within the nozzle will need to be removed periodically to maintain acceptable operation of the apparatus. However, as a result of the configuration of the nozzle, a cleaning process sufficient to remove such deposits from the nozzle will generally constitute a severe overetch of the remainder of the chamber surfaces. In some cases, the duration of a nozzle cleaning etch may be three or four times that necessary to clean the inner surfaces of the chamber. The repeated overetching of the inner wall of the chamber will tend to shorten lifespan of the deposition apparatus, lower the operating ratio of the apparatus, increase the maintenance costs and reduce the wafer throughput and productivity of the apparatus.

Further, as a result of the continuing trend toward larger diameter wafers, sources gases injected from a peripheral nozzle tend to be more concentrated at the wafer edges. This disparity in the source gas distribution increases the difficulty in achieving a substantially uniform deposition across the entire wafer surface during a deposition process.

### SUMMARY OF THE INVENTION

Exemplary embodiments of the present invention provide a plasma chemical vapor deposition apparatus including nozzles configured for reducing the excitation of sources gases within the nozzles and thereby suppressing or eliminating the formation of deposits on the inner walls of the nozzles. Exemplary embodiments of the present invention also provide a plasma chemical vapor deposition apparatus including both nozzles and injection pipes configured for producing a more uniform deposition across the entire surface of a wafer.

Exemplary configurations of plasma deposition apparatus according to the present invention will typically include a process chamber and a substrate supporter disposed within the process chamber to support a semiconductor substrate. A gas injection part is arranged and configured in the process chamber for injecting a source gas mixture into the process chamber with an energy source configured at an upper portion of the process chamber for applying sufficient energy to the source gas mixture within the process chamber to form a plasma.

The process chamber includes a dome-shaped upper chamber having an open bottom and a lower chamber having an open top. The lower chamber is disposed below the upper chamber and includes a substrate entry passage disposed at its sidewall. The substrate supporter is moved between the upper and lower chambers by means of a driving part.

The gas injection part has at least one nozzle and at least one injection pipe. A plurality of nozzles are regularly arranged in the lower chamber to be directed into the upper chamber. Each of the nozzles includes a single channel portion in which a passage of the source gas mixture is formed and a compound channel portion in which one or more passages of the source gas mixture is formed. The single channel portion is connected to a gas supply assembly, and the compound channel portion extends from the single channel portion. The respective passages of the compound channel portion are configured to have a smaller width than the passage of the single channel portion, thereby reducing or suppressing reaction of the source gas mixture in the nozzle. In the compound channel portion, each of the passages has a width of, at most, about 2 millimeters.

In some embodiments of the present invention, the compound channel portion includes at least one outer pipe in which a through-hole is formed to provide a passage for the source gas mixture and an insertion member inserted into the through-hole of the outer pipe to reduce the width of the passage of the outer pipe. The insertion member is fixedly connected to the compound channel region by means of the connection member. At least one insertion pipe may be provided between the outer pipe and the insertion member. The insertion pipe is fixedly connected to the compound channel portion by means of a connection member. A width between the outer pipe and the insertion pipe and a width between the insertion pipe and the insertion member are, at most, about 2 millimeters, respectively. The insertion member may be an inner pipe which provides another passage for the source gas mixture or, alternatively, a closed pipe or a solid rod that will divert the flow of the source gas mixture around the insertion member. An outlet end of the inner pipe may be disposed within the through-hole of the outer pipe or may be coplanarly disposed with an outlet end of the outer pipe. Alternatively, the outlet end of the inner pipe may be disposed to project from the outlet end of the outer pipe. The inner pipe has a diameter of, at most, about 2 millimeters. A width between the insertion member and the outer pipe is, at most, about 2 millimeters. In the case where the insertion pipe is provided, a width between the outer pipe and the insertion pipe and a width between the insertion pipe and the insertion member are, at most, about 2 millimeters, respectively.

In some embodiments of the present invention, the compound channel portion includes a plurality of through-holes' spaced apart from each other. They act as passages for the source gas mixture and each have a diameter of, at most, about 2 millimeters. The nozzle may further include a collecting region that extends from the compound channel portion and includes a through-hole disposed in its center. The compound channel portion has a length of at least 4 millimeters.

The injection pipe includes a main body in which a gas passage is formed and a projecting or outlet region projecting inwardly or outwardly toward the main body from a sidewall end of the main body. The main body has a closed outlet end, and the projecting region has one or more injection ports configured for injecting the source gas mixture and is shallower than the gas passage.

In some embodiments of the present invention, the projecting region includes the injection ports which are formed as a through-hole and spaced apart from each other. In other embodiments of the present invention, the projecting region includes a first injection port formed as a hole and one or more second injection ports being arranged in a generally ring-shaped configuration around the first injection port. In other embodiments of the present invention, the projecting region includes a generally ring-shaped inside injection port generally surrounded by one or more ring-shaped outside injection port.

Further, exemplary embodiments of the present invention provide a plurality of nozzles used in a plasma processing apparatus. The nozzles includes an outer pipe in which a through-hole is formed to provide a passage for the source gas mixture and an insertion member inserted into the through-hole of the outer pipe around an outlet end of the outer pipe. The insertion member is shorter than the outer pipe and is spaced apart from an inner wall of the outer pipe around an outlet end of the outer pipe where the source gas mixture is injected. The insertion member may be an inner pipe having a closed outlet end. Alternatively, the insertion member may be an inner pipe in which a through-hole is formed. An outlet end of the inner pipe is disposed in the through-hole of the outer pipe or is coplanarly disposed with an outlet end of the outer pipe. The outlet end of the inner pipe may be disposed to extend from the outlet end of the outer pipe.

While in most instances the source gas mixture will be injected from the outlet channel into the process chamber in a direction generally parallel with the longitudinal axis of the nozzle, the injection pipes and/or the nozzles may be configured to orient the output channels or injection ports at an angle relative to the longitudinal axis. This change in orientation may be achieved by including in the outlet end of the injection pipe or nozzle a thickened sidewall section through which the outlet channels or injection ports may be formed while maintaining dimensional configurations sufficient to suppress formation of a plasma within the nozzle and/or injection pipe.

### BRIEF DESCRIPTION OF THE DRAWINGS

The features and advantages of the present invention are described with reference to exemplary embodiments in association with the attached drawings in which similar reference numerals are used to indicate like or corresponding elements and in which:

FIG. 1 is a cross-sectional view of a high-density plasma chemical vapor deposition apparatus according to the present invention;

FIG. 2 is a schematic view of a gas supply part for supplying source gases to a nozzle shown in FIG. 1;

FIG. 3 is a perspective view showing an embodiment of the nozzle shown in FIG. 1;

FIG. 4 and FIG. 5 are a top plan view and a cross-sectional view taken along a line A-A of FIG. 3, respectively;

FIG. 6 and FIG. 7 are cross-sectional views showing alternative embodiments of the nozzle shown in FIG. 3;

FIG. 8 is a perspective view showing an alternative embodiment of the nozzle shown in FIG. 3;

FIG. 9 is a cross-sectional view taken along a line B-B of FIG. 8;

FIG. 10 is a perspective view showing another alternative embodiment of the nozzle shown in FIG. 3;

FIG. 11 is a cross-sectional view taken along a line C-C of FIG. 10;

FIG. 12 is a perspective view showing another embodiment of the nozzle shown in FIG. 3;

FIG. 13 is a cross-sectional view taken along a line D-D of FIG. 12;

FIG. 14 is a perspective view showing an alternative embodiment of the nozzle shown in FIG. 12;

FIG. 15 is a cross-sectional view taken along a line E-E of FIG. 14;

FIG. 16 is a cross-sectional view showing only a portion where an injection pipe and a nozzle are installed according to another embodiment of the apparatus of FIG. 1;

FIG. 17 is a front view showing an example of the injection pipe shown in FIG. 16;

FIG. 18 is a cross-sectional view taken along a line F-F of FIG. 17;

FIG. 19 is a front view showing an alternative embodiment of the injection pipe shown in FIG. 17;

FIG. 20 is a front view showing another alternative embodiment of the injection pipe shown in FIG. 17;

FIG. 21 is a front view showing another alternative embodiment of the injection pipe shown in FIG. 17;

FIG. 22 is a cross-sectional view taken along a line G-G of FIG. 21;

FIG. 23 is a cross-sectional view showing further another alternative embodiment of the injection pipe shown in FIG. 17; and

FIG. 24 is a cross-sectional view of a conventional nozzle.

These drawings have been provided to assist in the understanding of the exemplary embodiments of the invention as described in more detail below and should not be construed as unduly limiting the invention. In particular, the relative spacing, positioning, sizing and dimensions of the various elements illustrated in the drawings are not drawn to scale and may have been exaggerated, reduced or otherwise modified for the purpose of improved clarity. Those of ordinary skill in the art will also appreciate that a range of alternative configurations have been omitted simply to improve the clarity and reduce the number of drawings.

### DETAILED DESCRIPTION OF EXEMPLARY EMBODIMENTS

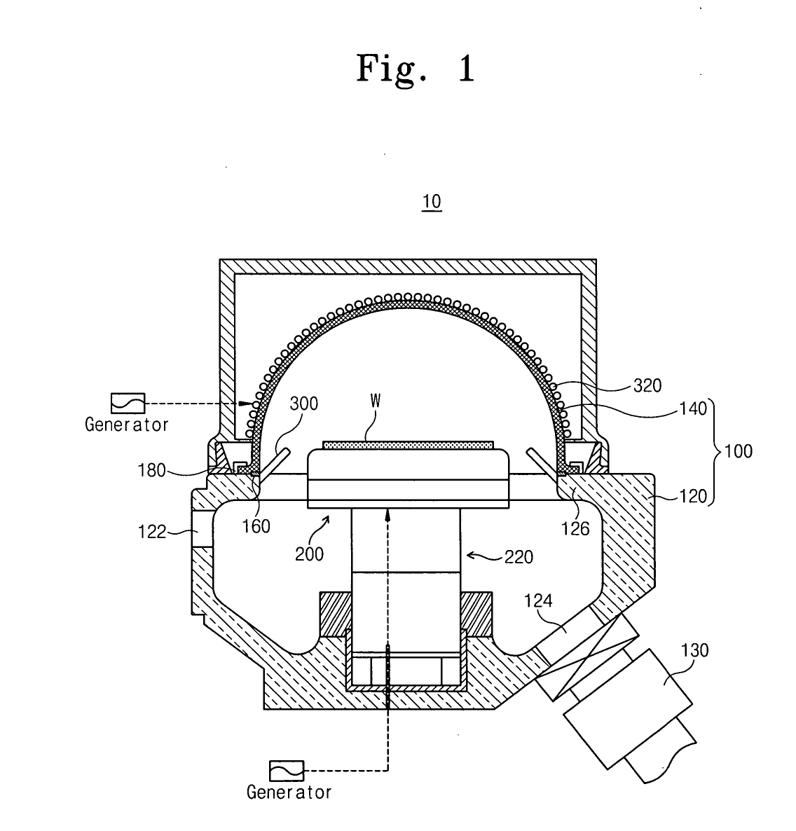

An exemplary high density plasma chemical vapor deposition (HDP-CVD) apparatus 10 according to the invention will now be described with reference to FIG. 1. As illustrated in FIG. 1, the HDP-CVD apparatus 10 includes a process chamber 100, a substrate supporter 200, a supporter driving part 220, an upper electrode 320, a lower electrode (not shown), and a gas injection part. The process chamber 100 provides a space in which deposition processes may be performed that may be sealed from the outside and maintained at pressures typically below atmospheric pressure.

As illustrated, the process chamber 100 includes both a lower chamber 120 and an upper chamber 140. An opening is provided in the upper portion of the lower chamber 120 for moving a wafer W into the upper chamber 140. One or more openings 122 may be provided in the sidewall of the lower chamber 120 for transferring wafers into and out of the lower chamber. An exhaust port 124 may be provided in a portion of the lower chamber 120 with an exhaust pipe 130 connected to the exhaust port for removing material from the process chamber. Undeposited reaction products, byproducts and unreacted gases resulting from a deposition process may be exhausted through the exhaust port 124. A vacuum pump (not shown) is typically connected to the exhaust pipe 130 for maintaining the sealed process chamber at one or more pressure(s), typically less than atmospheric pressure, during the deposition process.

A plate part 126 may be formed on the lower chamber 120 so as to project inwardly from the top of the sidewall and provide a surface for supporting and sealing the upper chamber 140 to the lower chamber. The upper chamber 140 may be a bell- or dome-shaped quartz structure having an open bottom. An O-ring 160 may be provided between opposing surfaces of the upper and lower chambers 140 and 120 for improved sealing of the process chamber 100. A cooling member 180 may be provided to limit deformation of the O-ring 160 resulting from heat absorbed from the process chamber during the deposition process.

An upper electrode 320 may be arranged over the exterior surface of the upper chamber 140 as coil and connected to a power source that may be capable of generating typically frequencies between about 100 kHz and 13.56 MHz and applying power typically between about 3,000 watts and 10,000 watts. The upper electrode 320 serves as an energy source applying or radiating energy into the chamber 100 to excite the source gases present in the upper chamber 140 to a level sufficient to form a plasma.

A substrate supporter 200 is provided in the lower chamber 120 for receiving and supporting a wafer W during the deposition process. The substrate supporter 200 may be an electrostatic chuck capable of holding the wafer on the chuck by an electrostatic force or may utilize other conventional methods of temporarily holding the wafer. Although not illustrated, a lift pin assembly may be provided under the substrate supporter 200 for lifting the wafer W from the surface of the chuck. The wafer W may be transferred into and out of the lower chamber 120 and onto and off of the substrate supporter 200 by a transfer robot (not shown).

A lower electrode (not shown) may be provided on or adjacent the substrate supporter 200 for applying a bias power and thereby draw or direct the plasma created in the process chamber 100 onto the exposed surface of wafer W. The bias power applied to the lower electrode may fall within a frequency range generally corresponding to that of the upper electrode 340, e.g., between about 100 kHz and 13.56 MHz and typically between about 1,500 watts and 5,000 watts.

The supporter driving assembly 220 is arranged for selectively moving the substrate supporter 200 from the lower chamber 120 up into the upper chamber 140 for processing and returning substrate supporter to the lower chamber when the processing is completed. Typically, a wafer W will be loaded into the lower chamber 120 and placed on the substrate supporter 200 that is positioned below the opening 122 using a robotic wafer transfer mechanism (not shown). The supporter driver assembly 220 will then be utilized to move the substrate supporter 200 and the wafer W into the upper portion of the lower chamber 120 or the upper chamber 140 for plasma processing. After the plasma processing has been completed, the substrate supporter 200 will be lowered and the wafer W will be removed from the chamber 100.

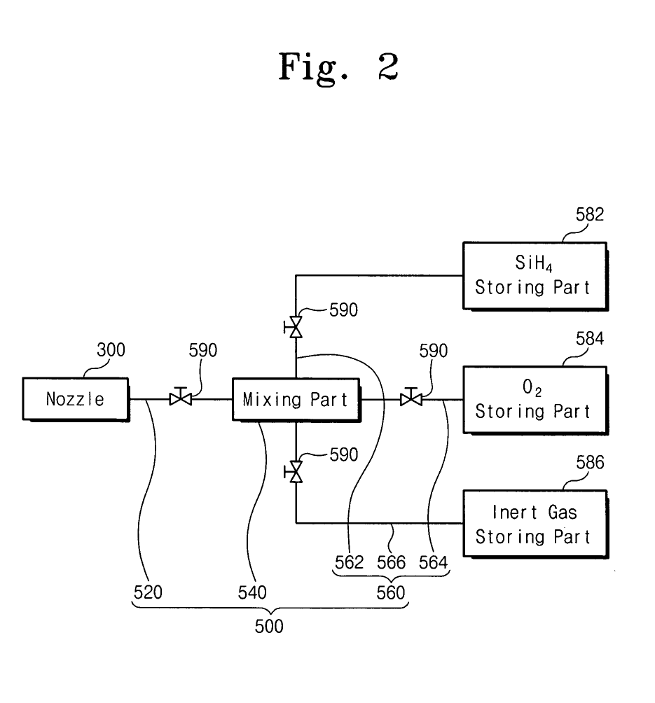

The source gases are supplied to the upper chamber 140 through the gas injecting part. The gas injecting part will typically include a nozzle assembly 300. The nozzle assembly 300 will typically include a plurality of perhaps eight or more separate nozzles arranged at regular intervals along an inner peripheral portion of the lower chamber 120 and directed to inject the source gas into a region in the upper chamber 140 above the wafer W. The nozzle assembly 300 is connected to and receives gases from a gas supply assembly (500 of FIG. 2). Each of the nozzles included in the nozzle assembly 300 is configured to receive and inject the same source gas mixture into the chamber during the deposition process.

An exemplary gas supply assembly 500 is schematically illustrated in FIG. 2. As illustrated, the gas supply assembly 500 includes a main line 520, a mixing region 540, a plurality of sub-lines 560 and gas storage elements 582, 584 and 586. Gases that may be provided to the nozzle assembly 300 are stored in the gas storage elements 582, 584, and 586, respectively and can be supplied to the mixing region 540 through their respective sub-lines 560.

When silicon oxide (SiO₂) is the material layer that is to be deposited on a wafer W, the gas provided through a first sub-line 562 may be silane (SiH₄) and a gas provided through the second sub-line 564 may be oxygen (O₂). In order to fill contact holes having a high aspect ratio, e.g., a height-to-width ratio of 5:1 or more, an inert gas such as helium (He) or argon (Ar) may be provided through a third sub-line 566 for inducing an etch process that will occur in combination with the primary silicon dioxide deposition process. Although not illustrated, the gas mixture provided to the chamber 100 through the nozzle assembly 300 may also include one or more carrier gases.

The gases are delivered in the proper amounts to the mixing region 540 through their respective sub-lines 562, 564 and 566 and are mixed there before being provided to the nozzle assembly 300 through the main line 520. A plurality of open/close valves 590 for opening/closing the various lines and sub-lines and a plurality of flow control valves (not shown), such as mass flow controllers (“MFC”) for controlling the relative flow rates of the various gases and the gas mixture may be installed the respective sub-lines 562, 564 and 566 and the main line 520.

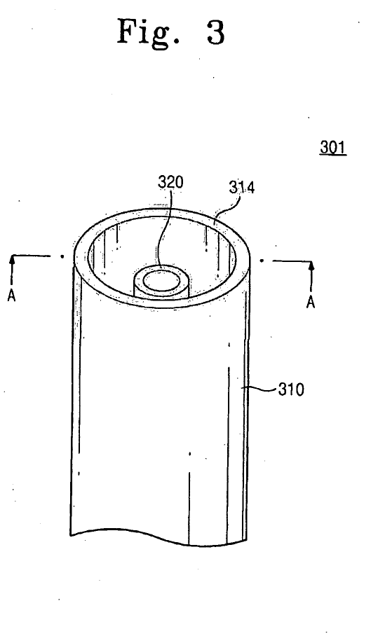

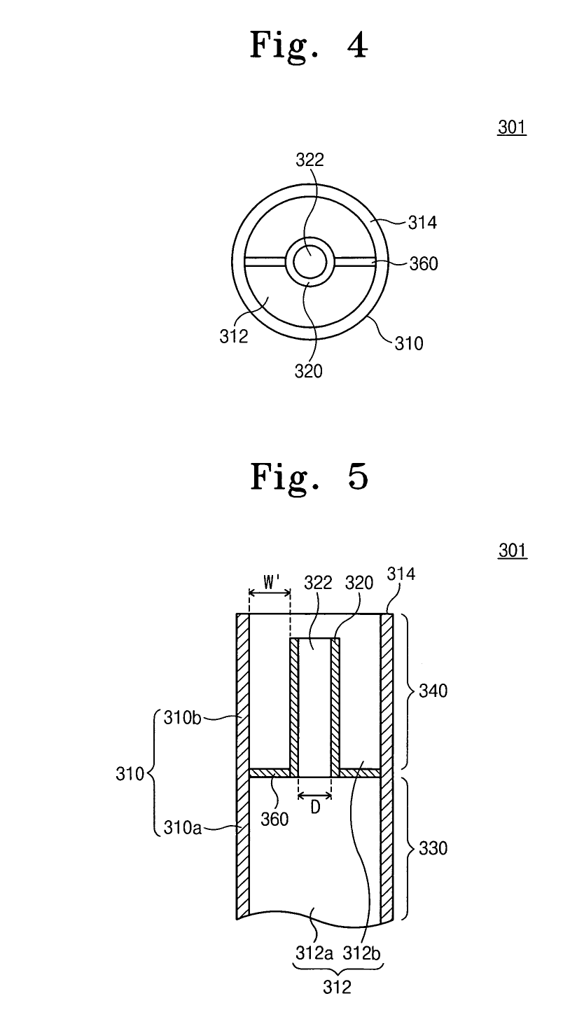

FIG. 3 is a perspective view of the outlet portion of a nozzle 301 from nozzle assembly 300 according to a first embodiment of the present invention, and FIG. 4 is a top plan view and FIG. 5 is a cross-sectional view taken along a line A-A of FIG. 3, respectively. As illustrated in FIGS. 3-5, the exemplary nozzle 301 includes an outer pipe 310, an insertion member and a connecting member 360 that positions the inner pipe within the outer pipe. The insertion member may be configured as a hollow pipe-shaped rod, which will be referred to infra as an inner pipe 320.

As illustrated in FIGS. 4 and 5, a generally circular through-hole 312a is defined by the inner wall of the outer pipe 310, having an annular outlet surface 314, below the inner pipe 320 and a generally annular through-hole 312b is defined between the inner surface of the outer pipe 310 and the outer surface of the inner pipe 320 at the outlet end of the nozzle 301 as an outlet for the source gas mixture. The inlet portion of the outer pipe 310 is, in turn, coupled or otherwise connected to a source gas supply assembly that may generally correspond to the configuration of the gas supply assembly 500 as detailed above. The smaller inner pipe 320 may be arranged substantially coaxially within and spaced apart from the larger outer pipe 310 near the outlet end of the outer pipe 310. The inner surface of the inner pipe 320 defines a second through-hole 322 that provides another outlet for the source gas mixture.

As illustrated, each of the nozzles 301 in the nozzle assembly 300 includes both an undivided single channel portion 330 in which the source gas will flow in a single through-hole and a compound or multi-channel portion 340 in which the source gas flow will be separated between at least two different through-holes. As may be appreciated from an examination of FIGS. 4 and 5, a source gas stream initially flowing along through-hole 312a in the single channel portion 330 will be divided between the annular through-hole 312b and central through-hole 322 as it reaches the compound channel portion 340.

As illustrated in FIGS. 4 and 5, the connecting member 360 used to position the inner pipe 320 within to the outer pipe 310 may configured as a rod or a blade (not shown). An inner end of each connecting member 360 may be fixedly coupled to the outer surface of the inner pipe 320 with the outer end of the connecting member being fixedly coupled to the inner wall of the outer pipe 310. The connecting member 360 may include only a single member or may include a plurality of members spaced at different around the interior of the outer pipe 310. If a plurality of connecting members 360 are utilized, they may be arranged at the same or different locations (not shown) along the outer pipe 310, may be regularly or irregularly (not shown) spaced and may be aligned in a generally radial or non-radial (not shown) fashion.

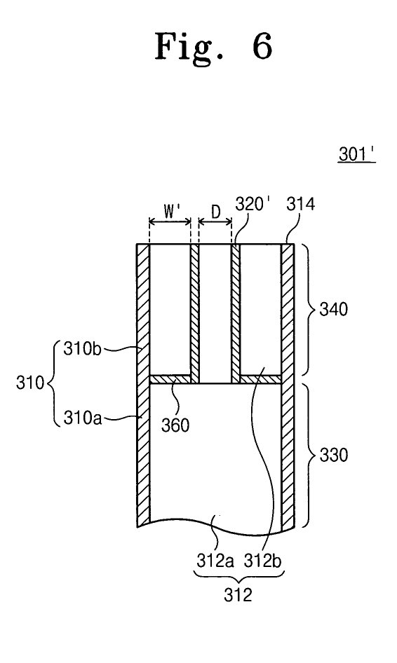

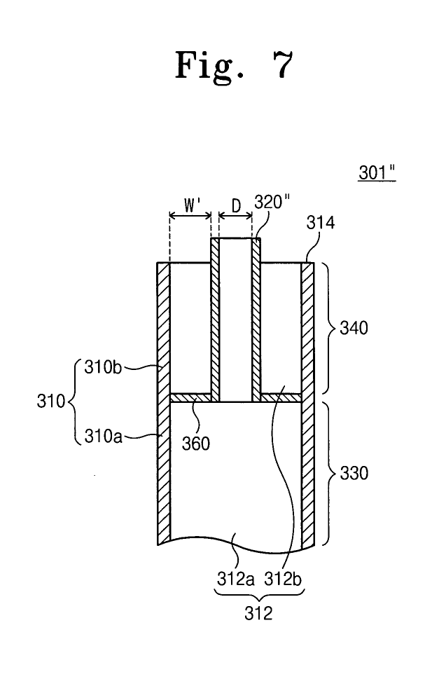

FIG. 6 and FIG. 7 are cross-sectional views of alternative nozzles 301′ and 301″ that are modified versions of the nozzle 301 illustrated in FIG. 3, respectively. As illustrated, the inner pipe may be variously disposed within the outer pipe in consideration of an injection pressure at which the source gases will be injected into the chamber 100. As illustrated in FIGS. 5-7, the inner pipe 320. 320′, 320″ may be arranged with its outlet end recessed relative to the outlet end of the outer pipe 310, FIG. 5, with its outlet end flush or coplanar with the outer pipe, FIG. 6, or with its outlet end extending past the outlet end of the outer pipe, FIG. 7.

FIG. 24 illustrates a conventional typical nozzle 600 in which only one through-hole 620 is formed. When nozzles configured as illustrated in FIG. 24 are utilized, the size of the opening or space within the nozzle 600 (particularly, a space around the end of the nozzle) is sufficiently large so that source gases flowing through the outlet portion of the nozzle may be converted into a plasma by energy absorbed from the power source applied to the upper electrode. The source gases excited into plasma form reaction products and byproducts that gradually build up a layer 605 at the end of the nozzle 600 and onto the inner wall thereof. Removing these deposits requires exposing the remainder of the plasma apparatus to an excessive amount of etching or increased maintenance required for disassembly of the nozzle assembly for external cleaning.

However, the nozzle 300 according to the invention includes a compound channel portion 340 that provide a plurality of gas passages that each have a smaller cross-sectional width W′ and diameter D adjacent the outlet injection portion of source gas. These smaller gas passages suppress the excitation of the source gas flowing through them, thereby reducing or substantially eliminating the formation of deposits on inner surfaces of the compound channel portion 340 relative to the deposits formed on a conventional single channel nozzle having generally the same total outlet area under similar process conditions.

In general, the nozzle components should be sized to limit the gap between two opposing surfaces to less than about 2 mm in the compound channel portion 340 of the nozzle. For example, nozzles 301, 301′ and 301″ may be constructed with the internal diameter D of the inner pipe 320 being no more than about 2 mm and the radial distance W′ between the outer surface of the inner pipe 320 and the inner wall of the outer pipe 310 also being no more than about 2 mm.

The overall length of the compound channel region 340 is another factor in the ability of nozzles according to the invention to suppress formation of a plasma within the nozzle. If the length of the compound channel region 340 is insufficient, enough energy may reach the source gases within the single channel portion 330 to form a plasma, resulting in the formation of deposits on the internal nozzle surfaces. The length of the compound channel region 340 sufficient to prevent formation of a plasma within the nozzle will be somewhat dependent on the concentration and velocity of the source gases, the operating pressure and the power applied. For conventional CVD processing that would include a cleaning process or cleaning cycle after every 5 to 10 wafers have been processed, it is expected that a compound channel region 340 length of at least about 4 mm may be adequate and a length of at least about 10 mm would provide an additional performance margin. Further, the length of the compound channel length 340 may be selectively varied according to the cleaning cycle. Generally, as the duration of the cleaning cycle is increased, the the length of the compound channel portion will also be increased.

As illustrated in FIGS. 5-7 and described above, one exemplary embodiment of the invention utilizes a simple inner pipe 320 has through-hole 322 corresponding to its full internal diameter. Those of skill in the art will appreciate, however, that alternative embodiments of the nozzle may include one or more inner pipes or simply an array of through-holes, of the same or variable sizes, spaced regularly or with some variation formed in the compound channel region of the nozzle.

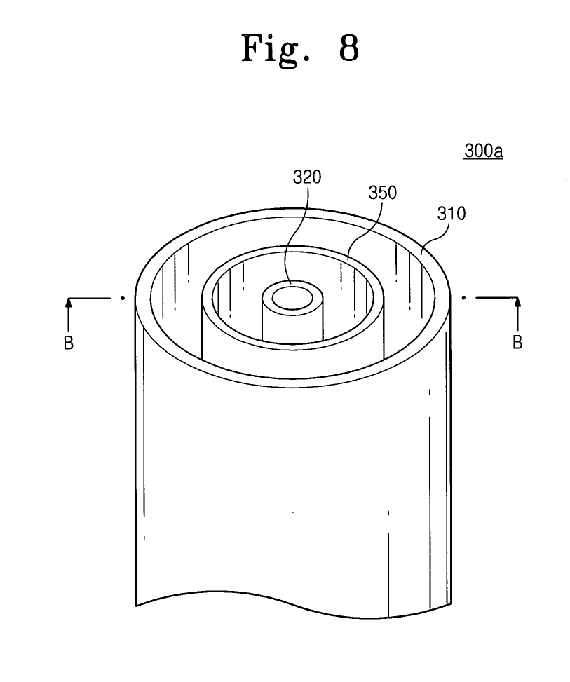

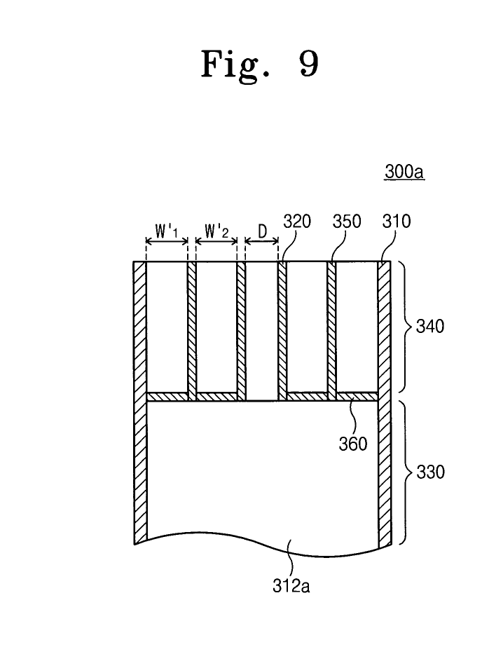

FIG. 8 is a perspective view showing another modified embodiment of the nozzle 300 shown in FIG. 3, and FIG. 9 is a perspective view taken along a line B-B of FIG. 8. As illustrated in FIGS. 8-9, an insertion pipe 350 is inserted between an outer pipe 310 and an inner pipe 320 of a nozzle 300a. The insertion pipe 350 is fixed to the nozzle 300a by means of a connection member 360. If a passage of the outer pipe 310 is wide, the width between the inner pipe 320 and the outer pipe 310 is long. Thus, when the inner pipe 320 is inserted into a compound channel portion 340, reaction of source gas mixture may occur in the compound channel portion 340. In order to prevent the reaction of the source gas mixture, the insertion pipe 350 serves to reduce the effective width between the inner pipe 320 and the outer pipe 310. Namely, with the insertion pipe 350 in place the original wide passage between the inner pipe 320 and the outer pipe 310 is divided into a plurality of more narrow passages to prevent excitation of source gas mixture into a plasma state therein. Preferably, the width W′₁ between an outer pipe and an insertion pipe and the width W′₂ between an inner pipe and the insertion pipe are, at most, about 2 millimeters. More preferably, the W′₁ and W′₂ range from about 1.5 mm to 2 mm. Although only one insertion pipe 350 is inserted in FIG. 8, a plurality of insertion pipes 350 may be inserted in proportion to the diameter of the outer pipe 310 to form the necessary number of reduced width regions W′₁ to W′ₙ.

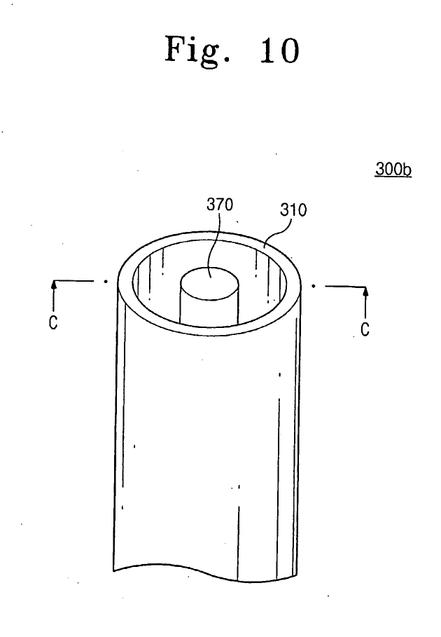

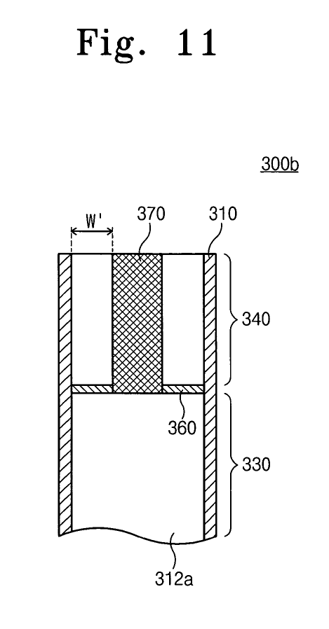

FIG. 10 is a perspective view showing still another modified embodiment of the nozzle 300 shown in FIG. 3, and FIG. 11 is a cross-sectional view taken along a line C-C of FIG. 10. As illustrated in FIGS. 10-11, instead of the above-mentioned inner pipe 320, a solid rod-shaped insertion member 370 is inserted into an outer pipe 310 of a nozzle 300b. If the width W′ of a passage formed at the outer pipe 310 is sufficient to excite source gas mixture into plasma but is insufficient to insert an inner pipe 320 in which a through-hole is formed, the insertion member 370 may be inserted into an outer pipe. The width between the inner pipe 320 and the insertion pipe 370 is preferably, at most, about 2 mm and, more preferably, ranges from about 1.5 mm to 2 mm.

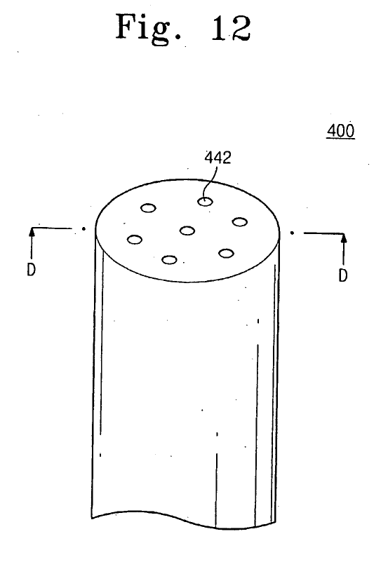

FIG. 12 is a perspective view of a nozzle 400 according to a second embodiment of the invention, and FIG. 13 is a cross-sectional view taken along a line D-D of FIG. 12. The nozzle 400 has a single channel region 430 and a compound channel region 440. The single channel region 430 may be substantially identical to the single channel region 330 described above with reference to the first embodiment. The compound channel region 440, however, may be configured somewhat differently than the compound channel region 340 described above with reference to the first embodiment. As illustrated in FIGS. 12 and 13, the compound channel portion 440 includes a plurality of discrete through-holes 442 spaced apart from each other.

Source gases flowing along the through-hole 432 will be distributed between and flow through the various through-holes 442 of the compound channel region 440 before being injected into a process chamber 100. As detailed with reference to the first embodiment, the sizing of the compound channel portion 440 should be made sufficient to suppress or prevent the source gases from forming a plasma before being ejected from the nozzle 400. In general, it is anticipated that for most CVD deposition processes a compound channel portion 440 having a length of at least 4 mm and perhaps at least 10 mm and utilizing through-holes 442 having an internal diameter D of not more than about 2 mm will provide sufficient suppression of plasma formation within the nozzle. Preferably the through-holes 442 have internal diameters D of not more than about 1.5 mm to 2 mm

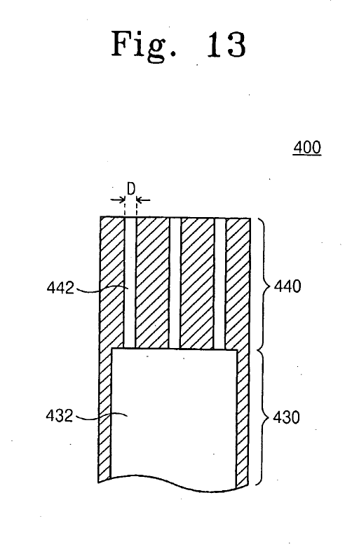

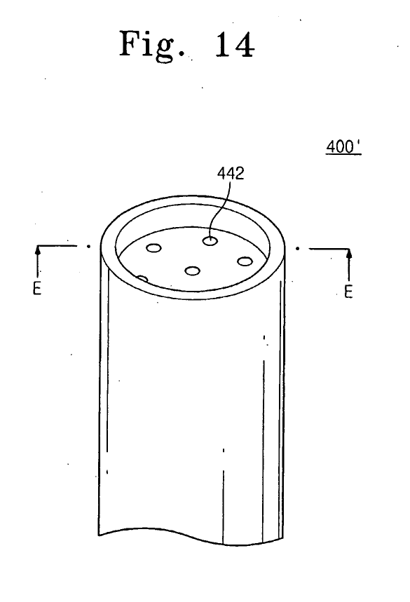

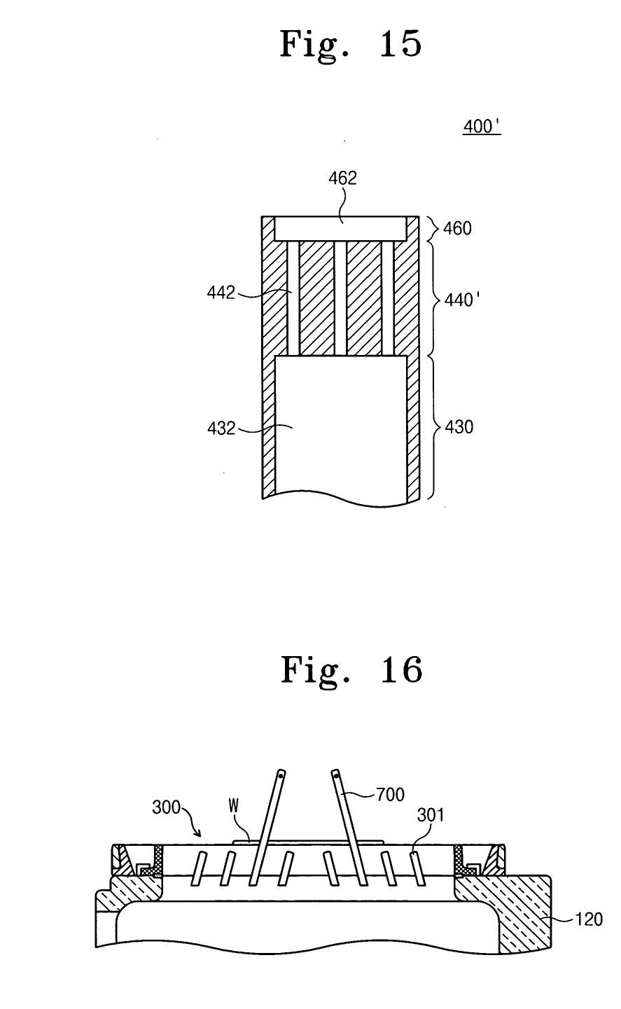

FIG. 14 is a perspective view showing a modified version of the nozzle 400 of FIG. 13, and FIG. 15 is a cross-sectional view taken along line E-E of FIG. 14. As illustrated in FIGS. 14 and 15, a nozzle 400′ includes a single channel region 430, a compound channel region 440′, and a collecting region 460. The single channel region 430 and the compound channel region 440′ may have the same basic configuration as detailed above with respect to the single channel region 430 and the compound channel region 440 of FIG. 12 and will not, therefore, be described in further detail. The collecting region 460 is formed in the final outlet portion of the nozzle 400′ between the compound channel region 440′ and the chamber 100 and may be configured to correspond generally to the single channel region 430. The combined lengths of the collecting region 460 and the compound channel region 440′ may be equal to the length of the compound channel region 440 of the exemplary nozzle configuration shown in FIG. 12. Varying the relative lengths of the collecting region 460 and the compound channel region 440′ in nozzle 400′ will provide a degree of control of the injection pressure as compared to the nozzle 400 illustrated in FIG. 12. Because the source gases will tend to form a plasma as they enter the collecting region 460 and deposits will be formed on the inner wall of the collecting part 460, the length of the collecting region 460 should allow it to be cleaned effectively during the cleaning process that is periodically applied to the inner surfaces of the process chamber 100.

FIG. 16 illustrates a modified example of a portion of the apparatus 10 of FIG. 1 according to another exemplary embodiment the present invention and provides a partial cross-sectional view highlighting the gas injection portion of the apparatus. As a result of the trend toward larger diameter wafers, source gases injected from a peripheral nozzle assembly 300 will be relatively concentrated toward the edge of a wafer W situated in the upper chamber 140. As a result, it is increasing difficult to obtain a substantially uniform deposition across the surface of a wafer W.

As illustrated in FIG. 16, the modified apparatus 10 includes a gas injection assembly that includes both injection pipes 700 and nozzles 301 provided on the injection assembly 300. The injection pipes 700 may be configured to receive and inject the same source gases or gas mixture as that provided to the nozzles 301. The injection pipes 700 are, however, configured to project further into chamber and inject the source gases farther above the wafer W than the nozzles 301. The outlet end of the injection pipes 700 may also be configured to direct the injected source gases toward a central portion in the upper chamber 140.

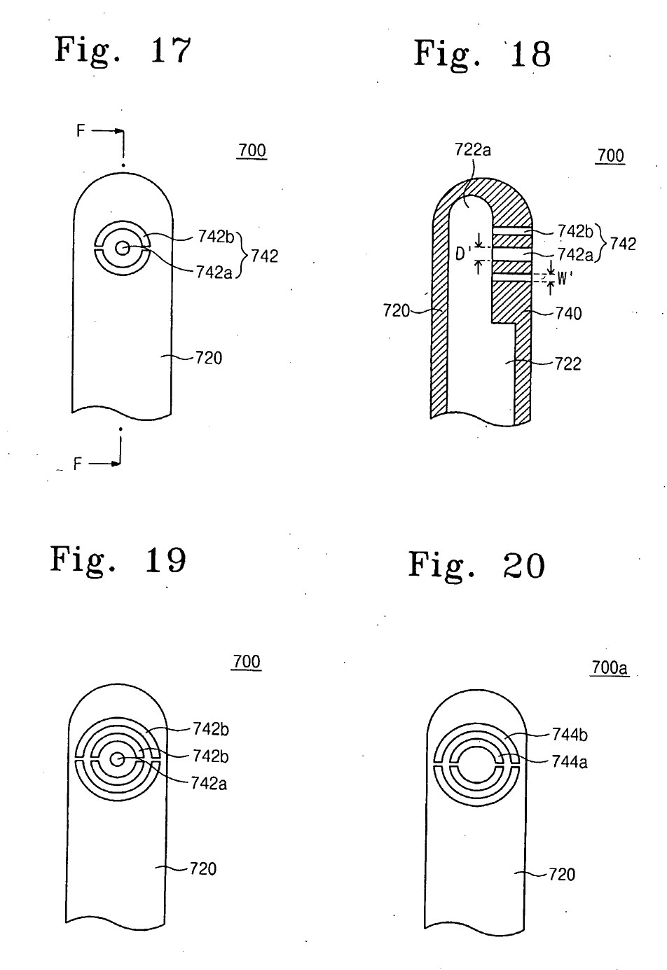

An exemplary embodiment of such an injection pipe 700 will now be described with reference to FIGS. 17 and 18. FIG. 18 is a front view of the injection pipe 700, and FIG. 14 is a cross-sectional view taken along a line F-F of FIG. 18. The injection pipe 700 includes a main body 720 and a projecting or outlet region 740. A gas passage 722 is provided through the main body 720 to conduct the source gases from a gas supply assembly 500 as detailed above or an equivalent gas distribution assembly to the outlet region 740.

The outlet region 740 may provide a reduced gas passage 722a as a result of a region of increased sidewall thickness provided for formation of outlet or injection openings. An injection port 742 may be formed through the thickened sidewall in the outlet region 740 to provide a path and a direction for injecting source gases flowing along the gas passages 722, 722a into the chamber. The length of the injection port 742 should be sufficient to suppress or eliminate the formation of a plasma within the gas passages 722, 722a to reduce the formation of deposits on the internal surfaces of the injection pipe 700. As with the nozzles 301, the length of the injection port 742 will, therefore, typically be at least 4 mm and possibly as much as 10 mm or more.

As illustrated in FIGS. 17 and 18, the injection port 742 may include a first central passage 742a and a second substantially circumferential passage 742b around the first passage. Selectively the injection port 742 may have a plurality of second substantially circumferential passages 742b as shown in FIG. 19. In order to suppress formation of a plasma within the injection pipe 700, the first and second passages 742a and 742b will typically be sized to have a maximum diameter D′, 742a, or maximum width W′, 742b, of no more than about 2 mm. Preferably the first and second passages 742a and 742b will be sized to diameters or widths of about 1.5 mm to 2 mm.

FIG. 20 is a top plan view showing a modified example of the injection pipe 700a. An inside injection port 744a and an outside injection port 744b are disposed at a projecting or outlet region 740 of an injection pipe. The inner injection port 744a is ring-shaped, and the outer injection port 744b is also ring-shaped and generally surrounds the inner injection port 744a. In order to prevent or suppress excitation of source gas mixture into a plasma state between the inner and outer injection ports 744a and 744b, they are preferably sized to have a width of at most 2 mm and, more preferably, a width within a range from about 1.5 mm to 2 mm.

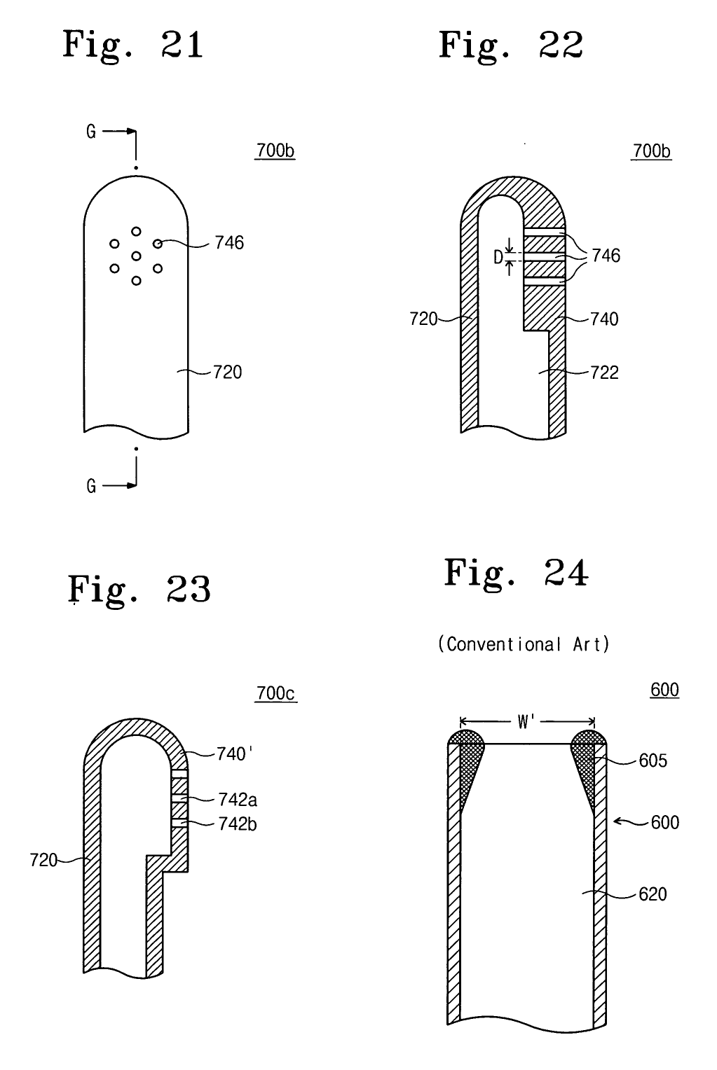

Another embodiment of an injection pipe 700b according to the present invention is illustrated in FIGS. 21 and 22. FIG. 21 is a front view of an injection pipe 700b, and FIG. 22 is a cross-sectional view taken along a line G-G of FIG. 21. As illustrated in FIGS. 21 and 22, the injection port 742′ may be configured with a plurality of holes spaced apart from each other. Again, in order to suppress or prevent the formation of a plasma within the injection pipe 700a or, more specifically, within the injection port 742′, each of the holes will typically provide a round or polygonal opening with a maximum diameter or width of no more than about 2 mm. Preferably each of the holes will provide an opening with diameter or width of about 1.5 mm to 2 mm. Although the holes may have the same size and shape, they may also be provided in a combination of sizes and/or shapes.

FIG. 23 is a cross-sectional view showing further another modified embodiment of the injection pipe 700c. As illustrated, an injection pipe 700c includes a projecting or outlet region 740′ which may project outwardly toward a main body 720. This may be applied to the injection pipes 700a, and 700b shown in FIGS. 20 and 21.

Although as illustrated in FIG. 16 and described in the corresponding text, the CVD deposition apparatus included a combination of both injection pipes 700 and nozzles 301 for injecting the same mixture of source gases into the process chamber 100, those skilled in the art will appreciate that alternative configurations may also be used. For example, the nozzles 301 may be removed so that the source gases are introduced only through an array of injection pipes 700, the nozzles 301 and injection pipes 700 may be supplied by different gas supply assemblies so as to be able to inject different combinations of source gases or control the proportion of the source gases supplied by the injection pipes relative to the nozzles. Similarly, first and second groups of nozzles 301 may be supplied by different gas supply assemblies or may be provided with differing outlet end structures to control the proportion of the source gases supplied to the chamber through each of the groups of nozzles.

Each of the nozzles and/or injection pipes configured according to the present invention will, however, be configured in a manner that will tend to suppress the formation of a plasma until the source gases have entered the chamber and thereby reduce the deposition of a material layer on internal surfaces of the nozzles or injection pipes. Nozzles and/or injection pipes configured according to the present invention, by reducing the deposition of material may be cleaned adequately during the conventional chamber cleaning process. By reducing or eliminating the need for additional cleaning of the nozzles and/or injection pipes, the present invention may be used to reduce the overetch of the chamber surfaces, increase the useable life of the chamber components, increase process throughput and/or reduce equipment maintenance and downtime. In addition, by utilizing injection pipes to inject source gases further from the wafer edges, a CVD deposition apparatus according to the present invention may provide improved deposition layer uniformity across the substrate wafer surface.

While the present invention has been described and illustrated with reference to certain exemplary embodiments, it should be understood that various modifications and substitutions may be made without departing from the spirit and scope of the invention as defined by the following claims.

1. A chemical vapor deposition (CVD) apparatus comprising:
a process chamber;
a substrate supporter, arranged and configured for supporting a substrate, disposed within the process chamber to support a substrate;
a gas injection part arranged and configured for injecting a source gas mixture into the process chamber through a nozzle; and
an energy source configured for applying sufficient energy to the source gas mixture within the process chamber to form a plasma,
wherein the nozzle includes:
a single channel portion through which a single passage for the source gas mixture is formed, the single channel portion being connected to a gas supply assembly; and
a compound channel portion through which two or more passages for the source gas mixture is formed, the compound channel portion extending from the single channel portion to an outlet portion,
wherein the respective passages of the compound channel portion are each configured to have a width W_{c} smaller than a width Wₚ of the passage of the single channel portion, the width W_{c} being sized for suppressing reaction of the source gas mixture within the nozzle.

2. The CVD apparatus according to claim 1, wherein:
the compound channel portion includes at least one outer pipe in which a through-hole is formed to provide a passage for the source gas mixture;
an insertion member inserted into the through-hole of the outer pipe to reduce the width of the passage of the outer pipe; and
a connection member configured for supporting and positioning the insertion member within the compound channel portion.

3. The CVD apparatus according to claim 2, wherein:
the compound channel portion further includes at least one insertion pipe arranged between the outer pipe and the insertion member, the connection member being configured for supporting and positioning the insertion pipe within the compound channel portion.

4. The CVD apparatus according to claim 3, wherein:
a width Wₒ defined between the outer pipe and the insertion pipe and a width Wᵢ defined between the insertion pipe and the insertion member are each no greater than about 2 millimeters.

5. The CVD apparatus according to claim 2, wherein:
the insertion member is an inner pipe.

6. The CVD apparatus according to claim 5, wherein:
an outlet end of the inner pipe is disposed within the through-hole of the outer pipe.

7. The CVD apparatus according to claim 5, wherein:
an outlet end of the inner pipe is disposed in a generally coplanar configuration with an outlet end of the outer pipe.

8. The CVD apparatus according to claim 5, wherein:
an outlet end of the inner pipe projects beyond a plane defined by an outlet end of the outer pipe.

9. The CVD apparatus according to claim 5, wherein:
the inner pipe has a diameter no greater than about 2 millimeters.

10. The CVD apparatus according to claim 2, wherein:
the width between the insertion member and the outer pipe no greater than about 2 millimeters.

11. The CVD apparatus according to claim 1, wherein:
the compound channel portion includes a plurality of through-holes spaced apart from each other, the through-holes providing a plurality of passages for the source gas mixture.

12. The CVD apparatus according to claim 11, wherein:
the nozzle further includes a collecting region that extends from an outlet end of the compound channel region.

13. The CVD apparatus according to claim 11, wherein:
the respective through-holes of the compound channel portion are generally circular and have a diameter no greater than about 2 millimeters.

14. The CVD apparatus according to claim 1, wherein:
the compound channel portion has a length of at least 4 millimeters.

15. The CVD apparatus according to claim 1, wherein:
the process chamber includes a dome-shaped upper chamber having an open bottom and a lower chamber having an open top, the lower chamber being disposed below the upper chamber and including a substrate entry passage disposed at its sidewall,
the CVD apparatus further comprising a driving part configured for moving the substrate supporter between the lower and upper chambers.

16. The CVD apparatus according to claim 15, further comprising:
a plurality of nozzles arranged regularly around the lower chamber and oriented to direct the source gas mixture into the upper chamber.

17. The CVD apparatus according to claim 1, further comprising:
a gas injection part configured for injecting the source gas mixture into the process chamber,
wherein the injection pipe includes:
a main body having a closed outlet end, through which a gas passage having a first width is formed; and
an outlet region formed through a sidewall region of the main body near the outlet end, the outlet region having one or more injection ports configured for injecting the source gas mixture into the process chamber, the injection ports having a depth less than the width of the gas passage.

18. The CVD apparatus according to claim 17, wherein:
the injection ports comprise a plurality of through-holes spaced apart from each other.

19. The CVD apparatus according to claim 18, wherein:
each of the plurality of through-holes has a diameter no greater than about 2 millimeters.

20. The CVD apparatus according to claim 17, wherein:
the outlet region includes a first injection port and at least one second injection port, the second injection port including arcuate openings that generally surround the first injection port.

21. The CVD apparatus according to claim 20, wherein:
the first injection port has a width W₁ and the second injection ports have a width W₂ of at most 2 millimeters.

22. The CVD apparatus according to claim 17, wherein:
the outlet region has a thickness of at least 4 millimeters.

23. The CVD apparatus according to claim 17, wherein:
the outlet region includes an inner injection port, the inner injection port including generally arcuate openings arranged about a center point to define a generally ring-shaped inner injection port.

24. The CVD apparatus according to claim 23, wherein:
the outlet region further includes an outer injection port, the outer injection port including generally arcuate openings arranged about the center point to define a generally ring-shaped outer injection port that surrounds and is generally coaxial with the inner injection port.

25. The CVD apparatus according to claim 24, wherein:
the inner injection port has a width W₁ measured in a generally radial direction of no greater than about 2 millimeters and
the outer injection port has a width W₂ measured in a generally radial direction of no greater than about 2 millimeters.

26. The CVD apparatus according to claim 17, wherein:
the outlet end of the injection pipe extends in the direction of the reaction chamber further than the outlet end of the nozzle.

27. A chemical vapor deposition (CVD) apparatus for depositing a predetermined layer on a semiconductor substrate, comprising:
a process chamber;
a substrate supporter, arranged and configured for receiving and holding a substrate, disposed in the process chamber;
a plurality of nozzles arranged and configured for injecting source gas mixture into the process chamber; and
an upper electrode arranged and configured to apply sufficient power to the source gas mixture injected into the process chamber to excite source gas mixture into a plasma state,
wherein
each of the nozzles includes an outer pipe in which a through-hole provides a passage for the source gas mixture, an insertion member arranged within the through-hole at an outlet end of the outer pipe and spaced apart from an inner wall of the outer pipe, and a connection member configured for supporting and positioning the insertion member within the outer pipe, and further wherein the outer pipe is connected to a gas supply assembly; and
the insertion member extends along only a portion of the through-hole provided through the outer pipe.

28. The CVD apparatus according to claim 27, wherein:
each of the nozzles further includes at least one insertion pipe positioned within the outer pipe and surrounding the insertion member.

29. The CVD apparatus according to claim 27, wherein:
a space defined between an outer surface of the insertion member and an inner surface of the outer pipe is no greater than about 2 millimeters.

30. The CVD apparatus according to claim 27, wherein:
the insertion member is an inner pipe having a through-hole that provides a passage for the source gas mixture.

31. A plurality of nozzles used in a plasma processing apparatus to supply a source gas mixture to the apparatus, comprising:
an outer pipe in which a through-hole is formed to provide a passage for the source gas mixture;
an insertion member arranged within the through-hole at an outlet end of the outer pipe, the insertion member extending along a portion of the through-hole formed in outer pipe; and
an connection member configured for supporting and positioning the insertion member within the outer pipe.

32. The nozzles according to claim 31, wherein:
the insertion member is an inner pipe in which a through-hole is formed to provide a second passage for the source gas mixture.

33. The nozzles according to claim 32, wherein:
only one through-hole is formed in the center of the inner pipe.

34. The nozzles according to claim 33, wherein:
the through-hole of the inner pipe has a diameter no greater than about 2 millimeters.

35. The nozzles according to claim 31, wherein:
a space defined between an outer surface of the insertion member and an inner surface of the outer pipe is no greater than about 2 millimeters.

36. The nozzles according to claim 31, wherein:
one or more insertion pipes are arranged within the outer pipe and surround the insertion member.

37. The nozzles according to claim 36, wherein:
a width defined between an inner surface of the outer pipe and an outer surface of the insertion pipe is no greater than about 2 millimeters; and
a width defined between an inner surface of the insertion pipe and an outer surface of the insertion member is no greater than about 2 millimeters.

38. The nozzles according to claim 31, wherein:
the insertion member has a length of at least 4 millimeters.

39. An injection pipe used in a plasma processing apparatus to inject a source gas mixture into a reaction chamber, comprising:
a main body having a closed outlet end, through which a gas passage is formed; and
an outlet region formed through a sidewall region of the main body, the outlet region including at least one injection port configured for injecting the source gas mixture into the reaction chamber.

40. The injection pipe according to claim 39, wherein:
the injection port comprises a plurality of through-holes spaced apart from each other.

41. The injection pipe according to claim 40, wherein:
each of the plurality of through-holes of the injection port has a diameter no greater than about 2 millimeters.

42. The injection pipe according to claim 41, wherein:
the outlet region includes an inner injection port and at least one outer injection port, the outer injection port being arranged so as be substantially surrounding the inner injection port.

43. The injection pipe according to claim 39, wherein:
the inner injection port has a width no greater than about 2 millimeters and the outer injection port has a width no greater than about 2 millimeters.

44. The injection pipe according to claim 39, wherein:
the outlet region includes an inner injection port having generally arcuate openings arranged around a center point to define a generally ring-shaped inner injection port.

45. The injection pipe according to claim 44, wherein:
the outlet region includes at least one outer injection port having generally arcuate openings arranged around the center point to define a generally ring-shaped outer injection port that substantially surrounds the inner injection port.

46. The injection pipe according to claim 45, wherein:
the inner injection port has a width W₁ measured in a generally radial direction of no greater than about 2 millimeters and
the outer injection port has a width W₂ measured in a generally radial direction of no greater than about 2 millimeters.

47. The injection pipe according to claim 39, wherein:
the outlet region is formed through a sidewall portion that has a thickness at least 4 millimeters.

48. A chemical vapor deposition (CVD) apparatus comprising:
a process chamber;
a substrate supporter disposed in the process chamber for supporting a substrate;
a plurality of nozzles arranged and configured for injecting a source gas mixture into a lower region of the process chamber, each nozzle including a plurality of outlet channels, each of the outlet channels being arranged and configured so as to suppress formation of the plasma within the nozzle;
a plurality of injection pipes arranged and configured for injecting the source gas mixture into an upper region of the process chamber, each of the injection pipes including a transfer region and an outlet region, the outlet regions including a thickened sidewall through which an injection port is provided for directing the source gas mixture into the upper region of the process chamber, the injection port being arranged and configured so as to suppress formation of the plasma within the injection pipe; and
an energy source configured for applying sufficient energy to the source gas mixture within the process chamber to form a plasma.

49. A CVD apparatus according to claim 48, wherein:
the plurality of nozzles are connected to a first source gas mixture supply, the nozzles being arranged in a generally circumferential fashion around the substrate supporter for directing the first source gas mixture into a lower region of the process chamber; and
the plurality of injection pipes connected a second source gas mixture supply, the injection pipes arranged in a generally circumferential fashion around the substrate supporter for directing the second source gas mixture into a upper region of the process chamber.

50. A CVD apparatus according to claim 49, wherein:
the first source gas mixture and the second source gas mixture are substantially identical.

51. A nozzle supplying a source gas mixture into a plasma processing apparatus, comprising:
a single channel portion in which a passage of the source gas mixture is formed, the single channel portion being connected to a gas supply assembly; and
a compound channel portion in which a plurality of passages extending from the passage of the single channel portion are formed,
wherein the respective passages of the compound channel portion are narrower than the passage of the single channel portion, and the compound channel portion has a length sufficient to prevent the source mixture from being excited in the single channel portion.

52. The nozzle according to claim 51, wherein:
the length of the compound channel portion is at least 4 millimeters.

53. A nozzle configured for supplying a source gas mixture into a plasma processing apparatus, comprising:
a single channel portion connected to a gas supply assembly; and
a compound channel portion extending from the single channel portion,
wherein the source gas mixture is injected into the plasma processing apparatus through a passage formed at the single channel portion and a passage formed at the compound channel portion, the passage formed at the compound channel portion being narrower than the passage formed at the single channel portion for suppressing reaction of the source gas mixture within the nozzle.

54. The nozzle according to claim 53, wherein:
a length of the compound channel portion is at least 4 millimeters.

55. A nozzle supplying a source gas mixture into a plasma processing apparatus, comprising:
an outer pipe in which a through-hole is formed, the through-hole being connected to a gas supply assembly; and
an insertion member inserted into the through-hole of the outer pipe to supply the source gas mixture flowing along the through-hole into the plasma processing apparatus through a plurality of divided portions,
wherein the insertion member is located in a region adjacent to a terminal of the outer pipe and has a length sufficient to prevent the source mixture from being excited in the single channel portion.

56. The nozzle according to claim 54, wherein:
the length of the insertion member is at least 4 millimeters.

57. A nozzle supplying a source gas mixture into a plasma processing apparatus, comprising:
an outer pipe in which a through-hole is formed, the through-hole being connected to a gas supply assembly; and
an insertion member inserted into the through-hole of the outer pipe, adjacent to a terminal of the outer pipe, the insertion member dividing the through-hole of the outer pipe into a plurality of narrow portions for suppressing reaction of the source gas mixture within the nozzle.

58. The nozzle according to claim 57, wherein:
a length of the compound channel portion is at least 4 millimeters.

59. A method for supplying a source gas mixture into a plasma processing apparatus, comprising:
flowing the source gas mixture through a single channel portion of a nozzle in which a passage connected to a gas supply assembly is formed;
flowing the source gas mixture through a compound channel portion of the nozzle having a passage which is narrower than a passage of the single channel portion; and
injecting the source gas mixture to the plasma processing apparatus,
wherein the compound channel portion has a length sufficient to prevent the source mixture from being excited in the single channel portion.

60. The method according to claim 59, wherein:
the making the source gas mixture flow through the compound channel portion of the nozzle having the passage which is narrower than the passage of the single channel portion includes making the source gas mixture flow more than 4 millimeters therein.

61. A method for supplying a source gas mixture into a plasma processing apparatus, comprising:
flowing the source gas mixture along a through-hole formed at a nozzle connected to a gas supply assembly;
flowing the source gas mixture from the through-hole to a plurality of portions branching to be narrower than the through-hole; and
injecting the source gas mixture to the plasma processing apparatus,
wherein the branching portions have a length sufficient to prevent the source gas mixture from being excited at an internal portion of the through-hole

62. The method according to claim 61, wherein:
the making the source gas mixture flow from the through-hole to a plurality of portions branching to be narrower than the through-hole includes making the source gas mixture flow more than 4 millimeters therein.
